(19) United States
(12) Patent Application Publication
(10) Pub. No.: US 2015/0232325 A1
(43) Pub. Date: Aug. 20, 2015

(54) MICRO ELECTRO MECHANICAL SYSTEMS PACKAGE AND MANUFACTURING METHOD THEREOF

(71) Applicant: ChipMOS Technologies, Inc., Hsinchu (TW)

(72) Inventor: Shih-Wen CHOU, Hsinchu City (TW)

(21) Appl. No.: 14/593,352

(22) Filed: Jan. 9, 2015

(30) Foreign Application Priority Data
Feb. 14, 2014 (TW) 103104861

(51) Int. Cl. B81B 7/00; B81C 1/00

(52) U.S. Cl. CPC B81B 7/007; B81B 7/0058; B81C 1/00301; B81B 2201/0257; B81B 2207/097; B81B 2207/115; B81C 2203/0136

(57) ABSTRACT

An MEMS package and the manufacturing method thereof are disclosed. The MEMS package includes a package substrate, a block ring, an MEMS chip and an encapsulating material. The package substrate has an inner surface, a corresponding outer surface and a signal opening that penetrates the inner surface and outer surface. The package substrate further has at least one inner contact pad and at least one outer contact pad wherein the outer contact pad is disposed on the outer surface. The inner contact pad is electrically coupled to the outer contact pad. The block ring is disposed on the inner surface and surrounds the signal opening. The MEMS chip has an active surface, at least one sensor device and at least one chip contact pad, wherein the sensor device and the chip contact pad are disposed on the active surface. The active surface is attached to the block ring so that the sensor device is surrounded by the block ring. The chip contact pad is electrically coupled to the inner contact pad. The encapsulating material covers the MEMS chip, the outer side of the block ring and the inner contact pad.

### CROSS REFERENCE TO RELATED APPLICATION

This application claims priority to Taiwan Patent Document No. 103104861, filed on Feb. 14, 2014 with the Taiwan Patent Office, which is incorporated by reference in its entirety.

### BACKGROUND OF THE INVENTION

1. Field of the Invention

The present invention relates to a micro electro mechanical systems package and the manufacturing method thereof, more particularly, to a micro electro mechanical systems package and manufacturing method thereof with an opening.

2. Description of the Prior Art

Micro electro mechanical systems or MEMS are smart, tiny systems. It comprises sensing, processing, and actuating functions. MEMS integrate two or more electronic, mechanical, optical, chemical, biological, magneto, or other properties into a single or multiple chips. The applications of MEMS have an expansive range, and include manufacture, automation, information and communication, aerospace, transportation, civil engineering, environment protection, agriculture . . . etc. A typical example of an MEMS is a micro microphone. Micro microphones are widely equipped inside mobile devices. Micro microphones are formed in an MEMS chip, where the package of the MEMS chip must have an opening to sense the vibration of a sound wave.

Please refer to FIG. 6, which illustrates a conventional MEMS chip package. The MEMS chip package 600 is formed by attaching an MEMS chip 602, for example a microphone chip, on a package carrier 604, for example, a substrate. The MEMS chip 602 has a sensing region 606, and a plurality of contact points 608, where the contact points 608 are electrical connected to the package carrier 604 via a wire 610. A top cover 612 has an opening 614, and the opening 614 corresponds to the sensing region 606 and is fixed on the package carrier 604 to allow the sensing region 606 of the MEMS chip 602 to receive a sound wave from environment. The MEMS chip package 600 is soldered on a motherboard via a plurality of solder balls 616. Using the sensing region 606, the MEMS chip 602 can sense the sound wave and convert the sound wave into a digital signal to be further processed on the motherboard.

As shown in FIG. 6, the design of the opening 614 of the MEMS chip package 600 faces the top, and a containing space formed by the top cover 612 and package carrier 604 is not filling any filling material. Therefore external air, dust, vapor, or even water to enter the containing space easily through the opening 614. It is then highly possible that the MEMS chip 602 would be contaminated which would in turn affect its operation. Additionally, there is a need to make a extra mold for manufacturing the top cover 612, and increasing the cost.

### SUMMARY OF THE INVENTION

An aspect of the present invention is to provide a micro electro mechanical systems (MEMS) package and manufacturing method thereof that can simplify the package structure and manufacturing process, which would then lower the cost of production.

Another aspect of the present invention is to provide a micro electro mechanical systems (MEMS) package and manufacturing method thereof that has an opening that faces the motherboard, which lowers the possibility of the MEMS chip being contaminated.

Another aspect of the present invention is to provide a micro electro mechanical systems (MEMS) package and manufacturing method thereof that can protect the region beyond the MEMS chip sensor device from contamination, increasing the product reliability.

According to the aspect mentioned above, the present invention provides an MEMS chip package comprising: a package substrate, a block ring, an MEMS chip, and an encapsulating material. The package substrate having an inner surface, a corresponding outer surface, and a signal opening which penetrates the inner surface and the outer surface; the package substrate having at least one inner contact pad, at least one outer contact pad disposed on the outer surface, with the inner contact pad electrically coupling to the outer contact pad.

The block ring is disposed on the inner surface and surrounds the signal opening; the MEMS chip has an active surface, with the active surface having at least one sensor device and at least one chip contact pad, the active surface attached to the block ring so that the sensor device is surrounded by the block ring, the chip contact pad electrically coupled to the inner contact pad The encapsulating material covers the MEMS chip, the outer side of the block ring and the inner contact pad.

According to the aspect mentioned above, the present invention also provides an MEMS chip package comprising: a package substrate, a block ring, an MEMS chip, and an encapsulating material. The package substrate has an inner surface, a corresponding outer surface, and a signal opening and a wire opening that penetrates the inner surface and the outer surface, around the wire opening and between the inner surface and the outer surface having at least one inner contact pad, the outer surface having at least one outer contact pad, with the inner contact pad electrically coupled to the outer contact pad.

The block ring is disposed on the inner surface and surrounds the signal opening. The MEMS chip has an active surface, with the active surface having at least one sensor device and at least one chip contact pad. The active surface attaches to the block ring so that the sensor device is surrounded by the block ring; the chip contact pad is electrically coupled to the inner contact pad via a wire through the wire opening, and the encapsulating material covering the MEMS chip, the outer side of the block ring and the inner contact pad.

According to the aspect mentioned above, the present invention also provides an MEMS package method comprising: providing a package substrate, the package substrate having an inner surface, a corresponding outer surface, at least one wire opening and a signal opening penetrating the inner surface and the outer surface, a stair-like structure is formed on the periphery of the wire opening and between the inner surface and the outer surface and, at least one inner contact pad disposed on the stair-like structure, at least one outer contact pad disposed on the outer surface, and the inner contact pad electrically coupled to the outer contact pad. Forming a block ring on the inner surface and surrounding the signal opening, providing an MEMS chip, the MEMS chip having an active surface, the active surface having at least one sensor device and at least one chip contact pad, and the active surface attaching to the block ring so that the sensor device is surrounded by the block ring. Conducting a wire bonding process, the chip contact pad electrically coupling to the inner contact pad by a wire through the wire opening, and conducting a packaging process where an encapsulating material covers the MEMS chip, the outer side of the block ring, and the wire opening.

In some embodiments of the present invention, the MEMS package further comprises at least one solder ball disposed on the outer contact pad for being connected outside. The material of the block ring is a B-stage Epoxy and the sensor device comprises a voice sensor.

The MEMS package of the present invention uses the block ring surrounding the signal opening so that the sensor device, which is surrounded by the block ring, can receive a signal, such as a sound wave from environment. The block ring can also keep the other parts of the MEMS chip from being exposed to environmental contamination, which increases the reliability of the product.

In addition, the signal opening of the MEMS package of the present invention is on the same side of the solder ball which faces the motherboard and causes the possibility of the MEMS chip being contaminated by external particles to be lower which also protects the MEMS chip. Moreover, the encapsulating material of the MEMS package of the present invention can cover the region beyond the sensor device, reinforcing the protection of the MEMS chip, increasing the reliability and stability of the product.

### BRIEF DESCRIPTION OF THE APPENDED DRAWINGS

FIG. 1 to FIG. 3, and FIG. 4 and FIG. 5 are sectional schematic diagrams of each of the process steps of the MEMS package manufacturing method according to an embodiment of the present invention.

FIG. 3A is a schematic diagram illustrating the bottom side of the FIG. 3.

FIG. 6 is a schematic diagram of a prior art of an MEMS package.

### DETAILED DESCRIPTION OF THE INVENTION

The embodiments and the practical applications of the present invention will be described in the following paragraphs, so as to sufficiently explain the characteristics, spirits, and advantages of the invention.

It is worth noting that these embodiments are merely representative of the embodiments of the present invention, wherein examples of a specific method, apparatuses, conditions, materials, etc. are not intended to limit the invention or the corresponding embodiments of the invention.

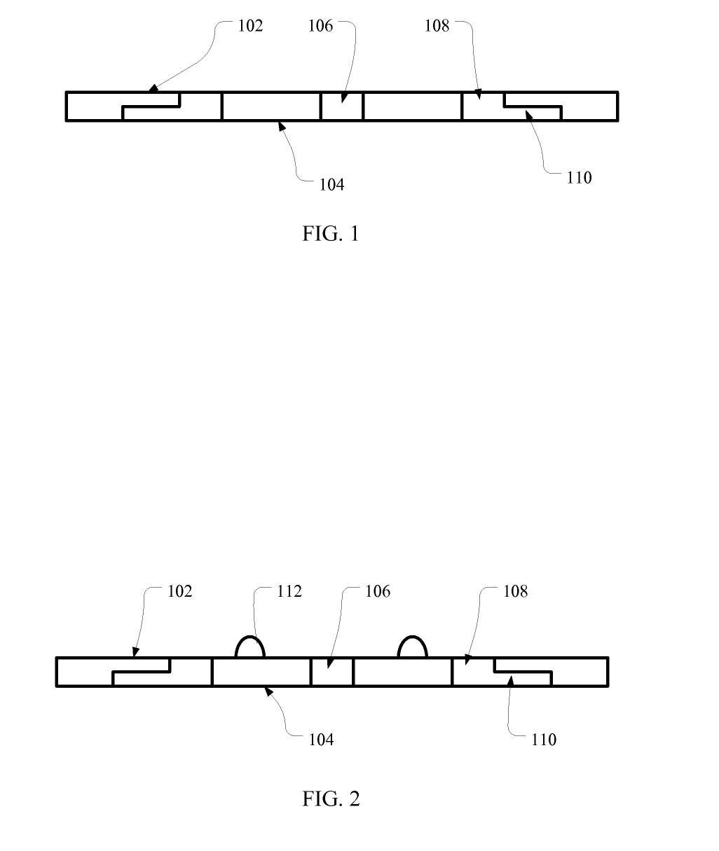

Please refer to FIG. 1 to FIG. 5, which are the sectional schematic diagrams of each of the process steps of an MEMS package manufacturing method according to an embodiment of the present invention.

First, please refer to FIG. 1. The package carrier of the MEMS package of the present invention is a package substrate 100. The package substrate 100 is ideally a ball grid array substrate. The package substrate 100 is composed by a multi-layer high density circuit board that has an inner surface 102, a corresponding outer surface 104, a signal opening 106 and at least one wire opening 108, with the signal opening 106 and the wire opening 108 penetrating the inner surface 102 and the outer surface 104.

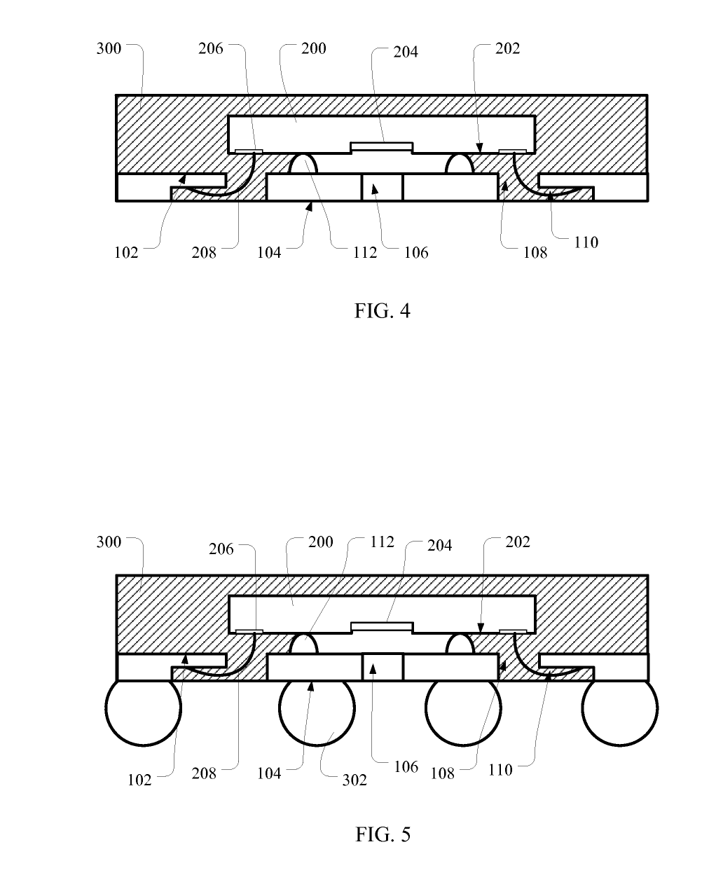

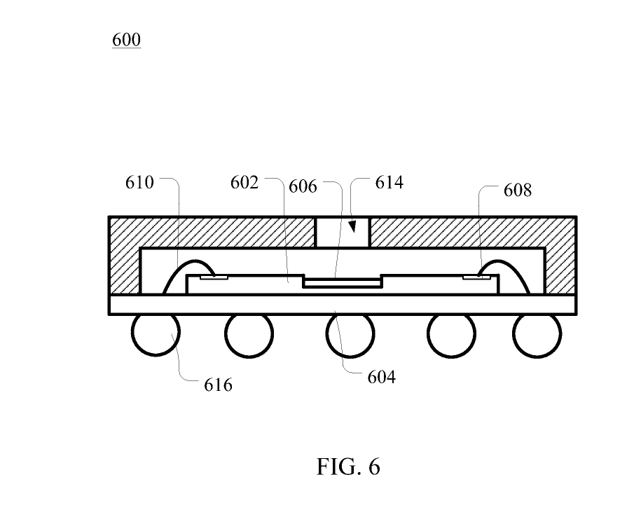

A stair-like structure 110 is forming on the periphery of the wire opening 108 and between the inner surface 102 and the outer surface 104, for example, one layer of the multi-layer circuit board and at least one inner connect pad 114 is disposed on the stair-like structure 110 (shown in FIG. 3A). At least one outer contact pad 116 is disposed on the outer surface 104 (shown in FIG. 3A), where the inner contact pad 114 is electrically coupled to the outer contact pad 116.

It is worth noting that the package substrate 100 in the embodiment of the present invention is not limited only to the ball grid array substrate, but can also be a PGA substrate, LGA substrate, flexible substrate, ceramic substrate, glass substrate, or any other kinds of substrates.

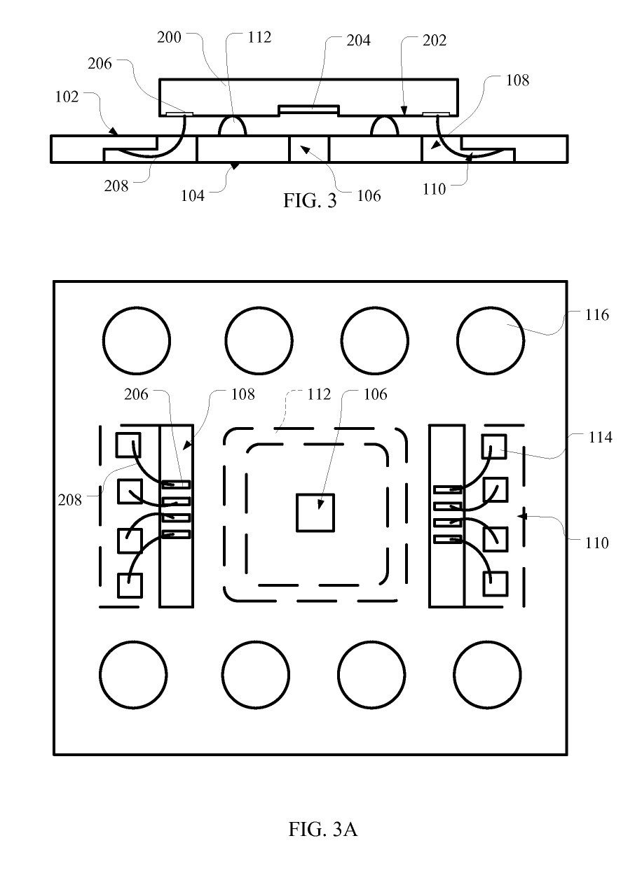

Next, please refer to the FIG. 2, where a block ring 112 is disposed on the inner surface 102. The block ring 112 can be formed by printing, attaching, or dispensing. The preferred material of the block ring 112 is a B-stage Epoxy. The block ring 112 surrounds the signal opening 106, wherein the block ring 112 can have a first stage curing process at a temperature of 90 to 150° C., where in 1 to 3 hours the block ring 112 will become a half-cure adhesion film (the cure temperature and time are adjustable with the manufacturing procedure).

Then, please refer to FIG. 3, which illustrates the present invention providing an MEMS chip 220, with the MEMS chip 200 having an active surface 202, the active surface 202 having at least one sensor device 204, such as an audio sensor device, and at least one chip contact pad 206. The active surface 202 of the MEMS chip 200 is attached to the block ring 112 so that the sensor device 204 is surrounded by the block ring 112 and corresponds to the signal opening 106. The chip contact pad 206 is electrically coupled to the inner contact pad 114 by a wire 208 through the wire opening 108. The wire 208 can be a gold wire, silver wire, copper wire, or any alloy wire thereof. It is worth noting that the connection method between the MEMS chip 200 and the package substrate 100 is not only through the wire bonding process, but also by Flip chip or Tape automatic bonding (TAB). On the other hand, the inner contact pad 114 is not only disposed on the stair-like structure 110, but also disposed on the inner surface 102 and directly connected to the MEMS chip wherein the signal opening 106 can be omitted. The inner connect pad 114 can also be disposed on the outer surface 104 and electrically coupled to the outer contact pad by the wire bonding process through the wire opening 108.

Please refer to FIG. 4, which illustrates the steps of the packaging process. An encapsulating material 300 covers the MEMS chip 200, the block ring 112, and the wire opening 108. In another embodiment of the present invention, a release film is pre-attached (not shown in figures) on the outer surface 104 of the package substrate 100, where the release film covers the signal opening 106 and the wire opening 108, and is then packaged with a mold. Therefore, on the active surface 202 of the MEMS chip 200, except for the region that the block ring 112 surrounds (including the sensor device), the rest are covered by the encapsulating material 300. The encapsulating material 300 not only covers the wire opening 108, but also the wire 208 and the inner contact pad 114. After the packaging process is finished, the release film (not shown in figures) is removed from the outer surface 104 of the package substrate 100, wherein the space that the signal opening 106, the block ring 112, and the sensor device 204 formed is not contained within the encapsulating material 300. This allows the sensor device 204 to still receive an external signal, like a sound wave, through the signal opening 106. As mentioned above, if the inner connection pad is disposed on the outer surface directly, the encapsulating material 300 would be prominent from the outer surface in order to cover the wire and the inner connection pad. During the same time as the packaging process, the block ring is in the second stage of the curing process at a temperature of about 130 to 180° C., in the time of about 1 to 3 hours (the curing temperature and time are adjustable with the manufacturing procedure). This is done in order to ensure the B-stage Epoxy completely cured, provides stable sustaining and adhering of the MEMS chip 200, and effectively blocks the MEMS chip 200 from contact with the external environment.

In another embodiment of the present invention, the second stage of the curing process of the block ring 112 can be done before the packaging process. That means, that after the heating and curing process are finished, and packaging process proceeds and achieves the same effect.

Please refer to FIG. 5 which shows the steps of the ball planting. Forming a solder ball 302 on the outer contact pad 116 (refer to FIG. 3A) is for connecting with the motherboard (or other components) afterwards. Now, the MEMS chip package of the present invention is complete. Thus, the MEMS package of the present invention mainly comprises a package substrate 100, a block ring 112, an MEMS chip 200, and an encapsulating material 300. The package substrate 100 has an inner surface 102, a corresponding outer surface 104, and a signal opening 106 that penetrates the inner surface 102 and the outer surface 104. The package substrate 100 has at least one inner contact pad 114, at least one outer contact pad 116 disposed on the outer surface, where the inner contact pad 114 is electrically coupled to the outer contact pad 116. The MEMS chip 200 has an active surface 202, where the active surface 202 has at least one sensor device 204 and at least one chip contact pad 206. The active surface 202 attaches to the block ring 112 so that the sensor device 204 is surrounded by the block ring 112 and the chip contact pad 206 is electrically coupled to the inner contact pad 114. The encapsulating material 300 covers the MEMS chip 200, the outer side of the block ring 112 and the inner contact pad 114. Wherein in the ideal embodiment, the package substrate 100 has at least one wire opening 108 which penetrates the inner surface 102 and the outer surface 104 with a stair-like structure 110 form on a periphery of the wire opening 108 and between the inner surface 102 and the outer surface 104, where at least one inner connect pad 114 is disposed on the stair-like structure 110, to help reduce the height of the wire 208 and the encapsulating thickness of the entire package structure.

In summary, the MEMS package of the present invention uses the block ring to surround the signal opening, so that the sensor device that is surrounded by the block ring can receive a signal, such as a sound wave, from the external environment. The block ring also keeps the other parts of the MEMS chip from contamination from the external environment for which increases the reliability of the product.

In addition, the signal opening of the MEMS package of the present invention is on the same side of the solder ball which faces the motherboard and causes the possibility of the MEMS chip being contaminated by external particles to be lower which also protects the MEMS chip. Moreover, the encapsulating material of the MEMS package of the present invention can cover the region beyond the sensor device, reinforcing the protection of the MEMS chip, increasing the reliability and stability of the product.

With the example and explanations above, the features and spirits of the invention will be hopefully well described. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An MEMS package comprising:
a package substrate, having an inner surface, a corresponding outer surface, at least one wire opening and a signal opening penetrating the inner surface and the outer surface, at least one inner contact pad disposed on a periphery of the wire opening and between the inner surface and the outer surface, at least one outer contact pad disposed on the outer surface, the inner contact pad electrically coupled to the outer contact pad;
a block ring, disposed on the inner surface and surrounding the signal opening;
an MEMS chip, having an active surface, the active surface having at least one sensor device and at least one chip contact pad, the active surface attached to the block ring so that the sensor device is surrounded by the block ring, the chip contact pad electrically coupled to the inner contact pad by a wire through the wire opening; and
an encapsulating material, covering the MEMS chip, the outer side of the block ring and the wire opening.

2. The MEMS package of claim 1, further comprising at least one solder ball disposed on the outer contact pad.

3. The MEMS package of claim 1, wherein material of the block ring is a B-stage Epoxy.

4. The MEMS package of claim 1, wherein the sensor device comprises a voice sensor.

5. The MEMS package of claim 1, wherein the package substrate has a stair-like structure form on a periphery of the wire opening and between the inner surface and the outer surface, and at least one inner connect pad disposed on the stair-like structure.

6. The MEMS package of claim 1, wherein the sensor device is disposed in the block ring, and corresponding to the signal opening.

7. The MEMS package of claim 1, wherein the encapsulating material covers the wire opening, the wire, and the inner contact pad.

8. An MEMS package method comprising:
providing a package substrate, the package substrate having an inner surface, a corresponding outer surface, at least one wire opening and a signal opening penetrating the inner surface and outer surface and, at least one inner contact pad disposed on a periphery of the wire opening and between the inner surface and outer surface, at least one outer contact pad disposed on the outer surface, the inner contact pad electrically coupled to the outer contact pad;
forming a block ring on the inner surface and surrounding the signal opening;
providing an MEMS chip, the MEMS chip having an active surface, the active surface having at least one sensor device and at least one chip contact pad, the active surface attached to the block ring so that the sensor device is surrounded by the block ring;
conducting a wire bonding process, the chip contact pad electrically coupled to the inner contact pad by a wire through the wire opening; and
conducting a packaging process, covering the MEMS chip, the outer side of the block ring and the wire opening by an encapsulating material.

9. The MEMS package method of claim 8, further comprising the step of forming at least one solder ball disposed on the outer contact pad.

10. The MEMS package method of claim 8, wherein the material of the block ring is a B-stage Epoxy, and the MEMS package method further comprises:
conducting a first curing process after the block ring is formed on the inner surface; and conducting a second curing process during the step of conducting the packaging process.

11. The MEMS package method of claim 8, wherein the sensor device comprises a voice sensor.

12. The MEMS package method of claim 8, further comprising the step of pre-attaching a release film on the outer surface of the package substrate before the step of conducting the packaging process, wherein the release film covers the signal opening and the wire opening, and packaged with a mold.

13. The MEMS package method of claim 12, further comprising the step of removing the release film from the outer surface of the package substrate after the step of conducting the packaging process.

14. An MEMS package comprising:
a package substrate, having an inner surface, a corresponding outer surface, and a signal opening penetrating the inner surface and outer surface, the package substrate having at least one inner contact pad, the outer surface having at least one outer contact pad, the inner contact pad electrically coupled to the outer contact pad;
a block ring, disposed on the inner surface and surrounding the signal opening;
an MEMS chip, having an active surface, the active surface having at least one sensor device and at least one chip contact pad, the active surface attached to the block ring so that the sensor device is surrounded by the block ring, the chip contact pad electrically coupled to the inner contact pad; and
an encapsulating material, covering the MEMS chip, the outer side of the block ring and the inner contact pad.

15. The MEMS package of claim 14, further comprising at least one solder ball disposed on the outer contact pad.

16. The MEMS package of claim 14, wherein the material of the block ring is a B-stage Epoxy.

17. The MEMS package of claim 14, wherein the sensor device comprises a voice sensor.

18. The MEMS package of claim 14, wherein the encapsulating material covers the wire opening, the wire, and the inner contact pad.
